(19) United States
(12) Patent Application Publication
(10) Pub. No.: US 2026/0319550 A1
(43) Pub. Date: Oct. 15, 2026

(54) PEN PLACEMENT STRUCTURE

(71) Applicant: QISDA CORPORATION, Taoyuan City (TW)

(72) Inventors: Jun-Wei CHIU, Taoyuan City (TW); Han-Hsiang LIAO, Taoyuan City (TW)

(73) Assignee: QISDA CORPORATION, Taoyuan City (TW)

(21) Appl. No.: 19/637,126

(22) Filed: Apr. 2, 2026

(30) Foreign Application Priority Data
Apr. 9, 2025 (CN) 202510440170.X

(51) Int. Cl. G06F 1/16; G06F 3/0354; H01F 7/02; H05K 5/02

(52) U.S. Cl. CPC G06F 1/166; G06F 3/03545; H01F 7/0268; H05K 5/0204; G06F 2200/1632

(57) ABSTRACT

A pen placement structure includes a storage portion and a mating portion. The storage portion has opposite first and second ends along a longitudinal axis, the first end having an opening. The mating portion includes a first magnetic member, the mating portion is selectively magnetically attached to the first end of the storage portion or to the bottom of an electronic device via the first magnetic member. When the mating portion is magnetically attached to the first end of the storage portion to close the opening, the interiors of the storage portion and the mating portion are in communication to form a pen holding space. When the mating portion is magnetically attached to the bottom of the electronic device, the mating portion supports the electronic device at its bottom. The pen placement structure provides both storage and stand functions.

This application claims the benefit of People’s Republic of China patent application Serial No. 202510440170.X, filed Apr. 9, 2025, the invention of which are incorporated by reference herein in its entirety.

### TECHNICAL FIELD

The present invention relates to a pen placement structure, and more particularly to a pen placement structure that simultaneously provides storage and stand functions.

### BACKGROUND

A stylus is a common peripheral device for electronic apparatuses, used for writing or drawing to enhance user convenience. A stylus with a magnetic attachment function has been commercially available, which can be magnetically attached to one side of an electronic device for storage. However, such a storage manner may easily result in loss of the stylus due to insufficient magnetic attraction. Another type of stylus storage structure is a pen insertion structure made of an elastic fabric and disposed on one side of the electronic device. Nevertheless, excessive use may cause the pen insertion structure to lose its elasticity, thereby leading to a risk of loss.

### SUMMARY

The present invention relates to a pen placement structure capable of preventing a stylus from being lost, and the pen placement structure may also serve as a stand for an electronic device.

According to one aspect of the present invention, a pen placement structure is provided. The pen placement structure includes a storage portion and a mating portion. The storage portion has a first end and a second end opposite each other along a longitudinal axis, the first end having an opening. The mating portion includes a first magnetic member, and the mating portion is selectively magnetically attached to the first end of the storage portion or to the bottom of an electronic device via the first magnetic member. When the mating portion is magnetically attached to the first end of the storage portion to close the opening, the interiors of the storage portion and the mating portion are in communication to form a pen holding space. When the mating portion is magnetically attached to the bottom of the electronic device, the mating portion supports the electronic device at the bottom of the electronic device.

Preferably, the storage portion includes a second magnetic member located at the first end, and the storage portion is selectively magnetically attached to the first magnetic member of the mating portion or to the bottom of the electronic device via the second magnetic member. When the storage portion is magnetically attached to the bottom of the electronic device, the storage portion supports the electronic device at the bottom of the electronic device.

Preferably, the mating portion has a third end and a fourth end opposite each other along the longitudinal axis, the third end is an open end, and the first magnetic member is located at the third end.

Further preferably, the second end is a closed end; and/or the fourth end is a closed end.

Further preferably, the storage portion includes a first end member and a first tubular member, the first end member is disposed on the first tubular member and located at the second end of the storage portion. The mating portion includes a second end member and a second tubular member, the second end member is disposed on the second tubular member and located at the fourth end of the mating portion. The first end member and the second end member respectively include a third magnetic member and a fourth magnetic member, the first end member and the second end member are selectively magnetically attached to the first tubular member and the second tubular member or to the bottom of the electronic device via the third magnetic member and the fourth magnetic member. When the first end member and the second end member are magnetically attached to the bottom of the electronic device, the first end member and the second end member support the electronic device at the bottom of the electronic device.

Further preferably, the first end member and/or the second end member includes a non-slip portion.

Further preferably, the first end member and/or the second end member has a hemispherical or domed shape.

Further preferably, the first tubular member includes a first tubular housing and a first magnetic attracting member, the first magnetic attracting member is disposed on one end of the first tubular housing to be magnetically attached to the third magnetic member. The second tubular member includes a second tubular housing and a second magnetic attracting member, the second magnetic attracting member is disposed on one end of the second tubular housing to be magnetically attached to the fourth magnetic member.

Preferably, the storage portion includes a tubular member and a first end member, the first end member is disposed on the tubular member and located at the second end of the storage portion. The first end member includes a second magnetic member, the first end member is selectively magnetically attached to the tubular member or to the bottom of the electronic device via the second magnetic member. When the first end member is magnetically attached to the bottom of the electronic device, the first end member supports the electronic device at the bottom of the electronic device.

Further preferably, the mating portion is a second end member having a shape corresponding to the first end member, the first end member and/or the second end member includes a non-slip portion.

Further preferably, the mating portion is a second end member having a shape corresponding to the first end member, the first end member and/or the second end member has a hemispherical or domed shape.

Preferably, the pen placement structure further includes a pen supporting seat disposed within the pen holding space.

Compared with the prior art, embodiments of the present invention provide a pen placement structure including a storage portion, a coupling portion and a mating portion. The storage portion has a first end and a second end opposite each other along a longitudinal axis, and the first end has an opening. The coupling portion partially protrudes from the storage portion, so as to be connected to one side of an electronic device. The mating portion includes a first magnetic member, and the mating portion is selectively magnetically attached to the first end of the storage portion or to a bottom of the electronic device via the first magnetic member. When the mating portion is magnetically attached to the first end of the storage portion to close the opening, interiors of the storage portion and the mating portion are in communication with each other to form a pen holding space. When the mating portion is magnetically attached to the bottom of the electronic device, the mating portion supports the electronic device at the bottom of the electronic device.

In order to better understand the above and other aspects of the present invention, embodiments are described below in detail with reference to the accompanying drawings.

### BRIEF DESCRIPTION OF THE DRAWINGS

FIG. 1 is a perspective view of a pen placement structure according to one embodiment of the present invention.

FIG. 2 is a partially exploded view of the pen placement structure of FIG. 1.

FIG. 3 is a further exploded view of the pen placement structure of FIG. 2.

FIG. 4 is a perspective view of an electronic device according to one embodiment of the present invention.

FIG. 5 illustrates the pen placement structure used for storage purposes.

FIG. 6A illustrates one embodiment in which the pen placement structure is used as a stand for the electronic device.

FIG. 6B shows the embodiment of FIG. 6A from another perspective.

FIG. 7A illustrates another embodiment in which the pen placement structure is used as a stand for the electronic device.

FIG. 7B shows the embodiment of FIG. 7A from another perspective.

FIG. 8 is a perspective view of a pen placement structure according to another embodiment of the present invention.

FIG. 9 is a partially exploded view of the pen placement structure of FIG. 8.

### DETAILED DESCRIPTION

For a better understanding of the objectives, structures, features and functions of the present invention, detailed descriptions in conjunction with embodiments are provided below.

Certain terms are used in the specification and the claims to refer to particular elements. It should be understood by those skilled in the art that a manufacturer may refer to the same element by different names. Distinctions between elements in the present specification and claims are therefore not based on the names used, but rather on functional differences between the elements. The term “including” or “comprising” as used throughout the specification and the claims is intended to be an inclusive term, and should be interpreted as “including, but not limited to.”

The ordinal terms such as “first,” “second,” “third” and the like used in the present specification are intended merely to distinguish elements from one another, and do not imply any prior sequence of the elements, nor do they indicate any order or sequence between the elements or in the manufacturing process. The use of such ordinal terms is solely for the purpose of clearly distinguishing one element having a given designation from another element having the same or similar designation.

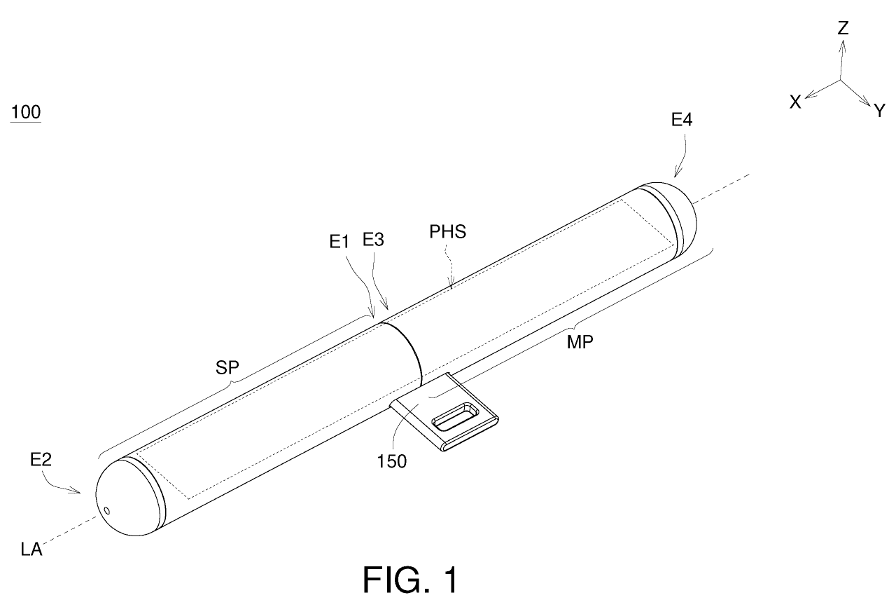

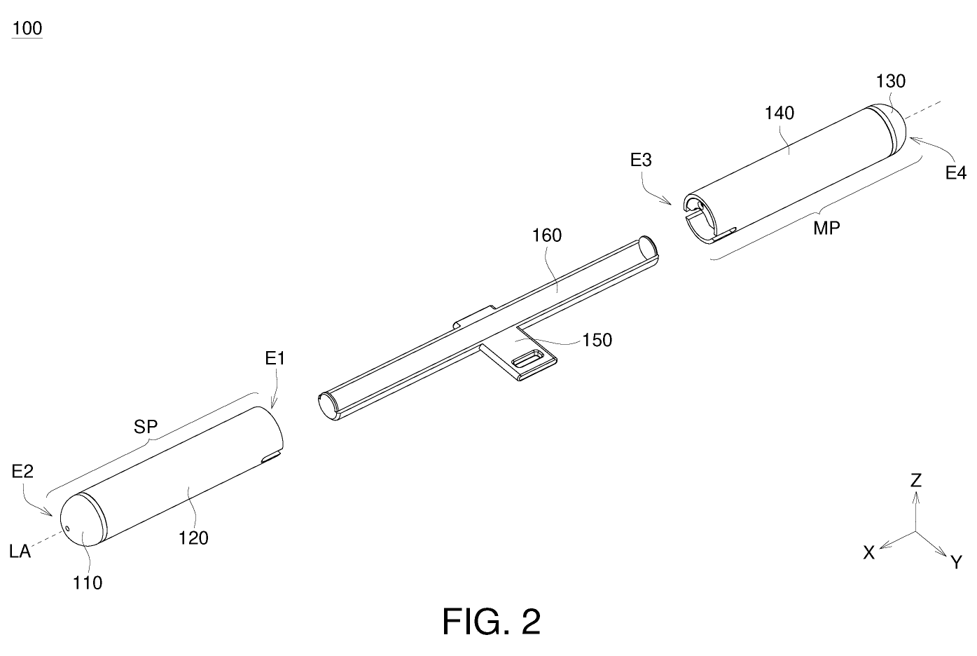

FIG. 1 is a perspective view of a pen placement structure 100 according to one embodiment of the present invention. FIG. 2 is a partially exploded view of the pen placement structure 100 of FIG. 1.

Referring to FIGS. 1 and 2, the pen placement structure 100 may be a rod-shaped elongated structure and at least includes a storage portion SP and a mating portion MP. The storage portion SP and the mating portion MP may be separated from or coupled to each other. The storage portion SP is an elongated extension member having a longitudinal axis LA. The storage portion SP has a first end E1 and a second end E2 opposite each other along the longitudinal axis LA. In the present embodiment, the mating portion MP is also an elongated extension member and has a third end E3 and a fourth end E4 along the longitudinal axis LA. The third end E3 of the mating portion MP may be coupled to or detached from the first end E1 of the storage portion SP.

In one embodiment, the pen placement structure 100 may include a coupling portion 150 and a pen supporting seat 160. A stylus may be placed on the pen supporting seat 160. The coupling portion 150 may be disposed on the pen supporting seat 160. In another embodiment, as shown in FIG. 2, the second end E2 of the storage portion SP and the fourth end E4 of the mating portion MP are closed ends. In yet another embodiment, the second end E2 of the storage portion SP and the fourth end E4 of the mating portion MP may each have an opening with a diameter smaller than that of the stylus, so as to prevent the stylus from falling out from the second end E2 or the fourth end E4, and to allow a user to visually confirm through the opening whether a stylus is placed inside the pen placement structure 100; however, the present application is not limited thereto. As further shown in FIG. 2, the third end E3 of the mating portion MP is an open end having an opening; it is to be understood that, although not shown in FIG. 2 due to visual obstruction, the first end E1 of the storage portion SP also has an opening. The pen supporting seat 160 may be received inside the storage portion SP and the mating portion MP respectively through the first end E1 of the storage portion SP and the third end E3 of the mating portion MP. When the third end E3 of the mating portion MP is coupled to the first end E1 of the storage portion SP to close the openings, the interiors of the storage portion SP and the mating portion MP are in communication with each other to form a pen holding space PHS for accommodating the stylus. Referring to FIGS. 1 and 2, the coupling portion 150 extends outward from a side cutout between the storage portion SP and the mating portion MP, and protrudes from the storage portion SP and the mating portion MP. In another embodiment, the pen supporting seat 160 may be omitted, such that the stylus may be directly accommodated in the pen holding space PHS jointly formed inside the storage portion SP and the mating portion MP, and the coupling portion 150 is provided protruding from the outer surface of the storage portion SP.

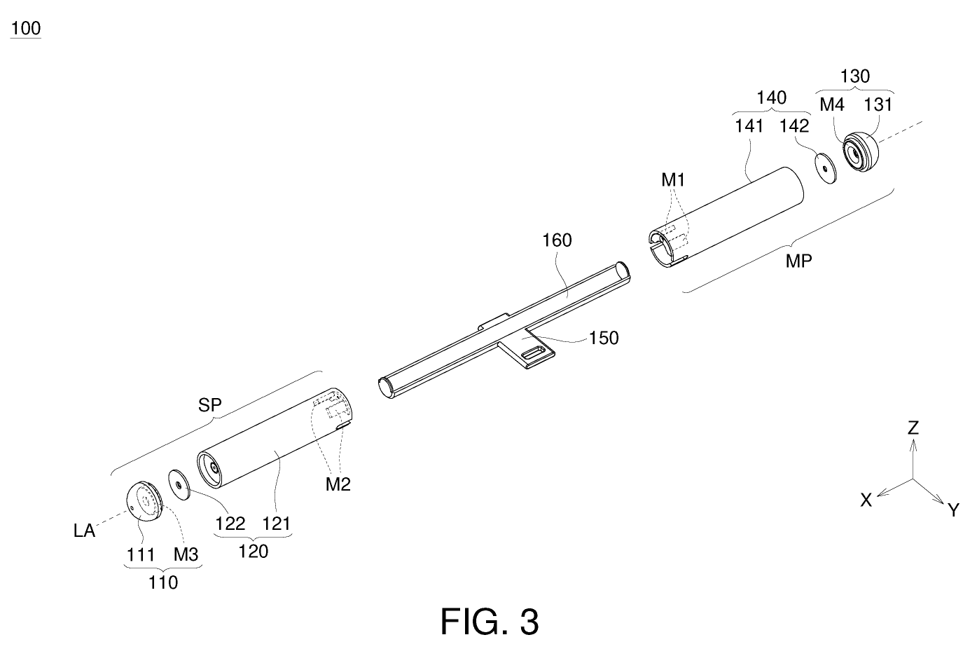

The third end E3 of the mating portion MP and the first end E1 of the storage portion SP may be coupled to each other through magnetic attraction. FIG. 3 is a further exploded view of the pen placement structure 100 of FIG. 2. Referring to FIGS. 1, 2 and 3, the mating portion MP may include a first magnetic member M1, and the storage portion SP may include a second magnetic member M2. The first magnetic member M1 and the second magnetic member M2 may be magnetic elements having ferromagnetic properties. The first magnetic member M1 may be disposed on the third end E3 of the mating portion MP, and the second magnetic member M2 may be disposed on the first end E1 of the storage portion SP. The first magnetic member M1 and the second magnetic member M2 correspond to each other and may be magnetically attracted to each other by opposite polarities, thereby allowing the mating portion MP and the storage portion SP to be coupled together and in communication to form the pen holding space PHS.

Referring to FIGS. 2 and 3, in one embodiment, the storage portion SP may include a first end member 110 and a first tubular member 120, and the mating portion MP may include a second end member 130 and a second tubular member 140. The first end member 110 is disposed on the first tubular member 120 and located at the second end E2 of the storage portion SP. The second end member 130 is disposed on the second tubular member 140 and located at the fourth end E4 of the mating portion MP. The first end member 110 and the second end member 130 may be respectively coupled to or detached from the first tubular member 120 and the second tubular member 140.

The first end member 110 and the second end member 130 may be magnetically coupled to the first tubular member 120 and the second tubular member 140, respectively. In one embodiment, the first end member 110 and the second end member 130 may respectively include a third magnetic member M3 and a fourth magnetic member M4. The third magnetic member M3 and the fourth magnetic member M4 may be magnetic elements having ferromagnetic properties. The first tubular member 120 and the second tubular member 140 may include materials having magnetic permeability, so that magnetic attraction can be generated between the third magnetic member M3 and the first tubular member 120, and between the fourth magnetic member M4 and the second tubular member 140. Therefore, the first end member 110 and the second end member 130 may be magnetically coupled to the first tubular member 120 and the second tubular member 140, respectively. For example, the first tubular member 120 may include a first tubular housing 121 and a first magnetic attracting member 122, and the second tubular member 140 may include a second tubular housing 141 and a second magnetic attracting member 142. The first magnetic attracting member 122 and the second magnetic attracting member 142 are respectively disposed on the ends of the first tubular housing 121 and the second tubular housing 141 facing toward the first end member 110 and the second end member 130, and are made of materials having magnetic permeability, so as to be magnetically attracted and fixed by the third magnetic member M3 and the fourth magnetic member M4, respectively.

Referring to FIG. 2, the first end member 110 and/or the second end member 130 may have a hemispherical or domed shape, but the present invention is not limited thereto. In other embodiments, the first end member 110 and/or the second end member 130 may have other shapes, such as square or other polygonal forms.

Referring to FIG. 3, the first end member 110 may include a non-slip portion 111. The non-slip portion 111 may be made of rubber, plastic, or a material treated on the surface to provide anti-slip properties. Similarly, the second end member 130 may also include a non-slip portion 131, which may likewise be made of rubber, plastic, or a material treated on the surface to provide anti-slip properties.

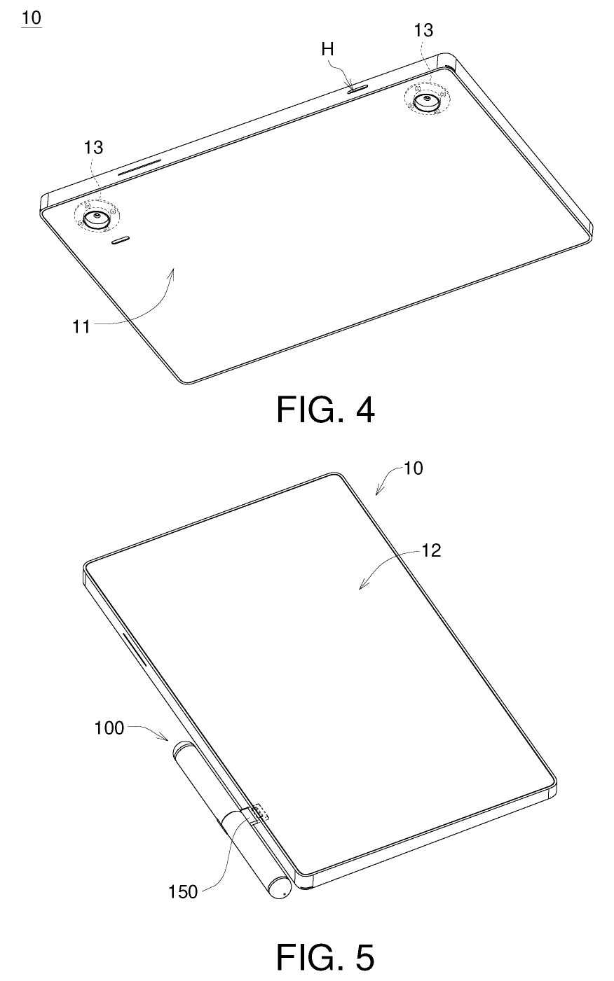

FIG. 4 is a perspective view of an electronic device 10 according to one embodiment of the present invention. FIG. 5 illustrates the pen placement structure 100 used for storage purposes.

Referring to FIGS. 4 and 5, the electronic device 10 may be a tablet computer, including a bottom 11 and a touch surface 12 disposed opposite each other. In addition, the electronic device 10 may have a slot H provided on one side of the electronic device 10. When the pen placement structure 100 is used for storage purposes, the coupling portion 150 of the pen placement structure 100 may be inserted into the slot H of the electronic device 10, or magnetically attached to one side of the electronic device 10, allowing the stylus to be stored inside the pen placement structure 100 to prevent loss. In one embodiment, when the coupling portion 150 is magnetically connected to the electronic device 10, the coupling portion 150 may directly contact the electronic device 10 for magnetic fixation, providing a relatively strong magnetic attraction. On the other hand, the pen placement structure 100 may also be used as a stand for the electronic device 10, and may provide the electronic device 10 with different supporting angles.

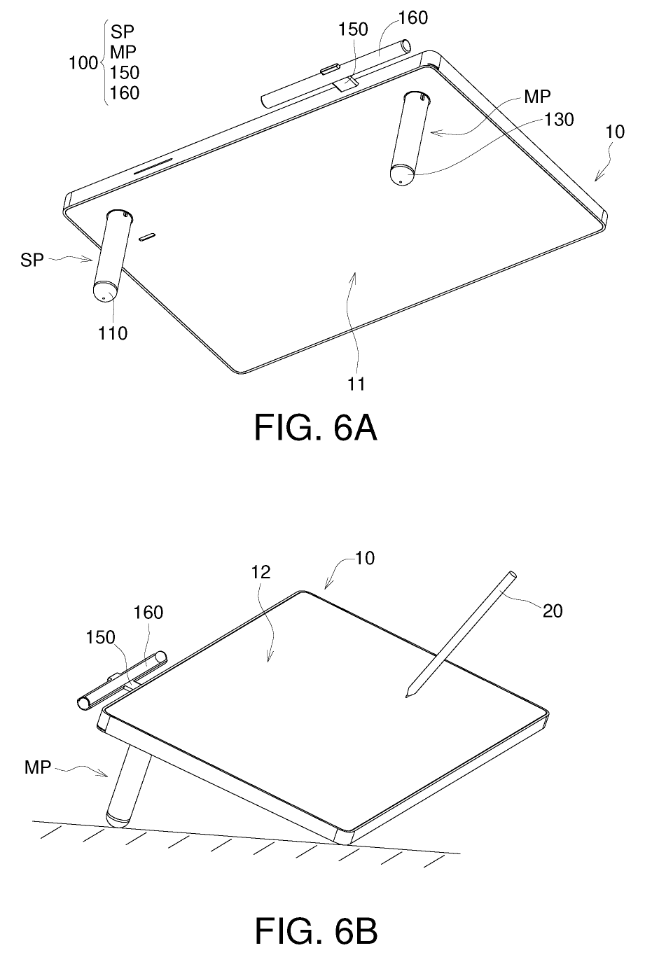

FIG. 6A illustrates one embodiment in which the pen placement structure 100 is used as a stand for the electronic device 10. FIG. 6B shows the embodiment of FIG. 6A from another perspective.

Referring to FIGS. 3, 6A and 6B, when the pen placement structure 100 is used as a stand for the electronic device 10, the storage portion SP and the mating portion MP may be separated from each other. The storage portion SP and the mating portion MP may be magnetically attached to the bottom 11 of the electronic device 10 via the second magnetic member M2 and the first magnetic member M1, respectively, allowing the storage portion SP and the mating portion MP to support the electronic device 10 at the bottom 11. This enables the user to comfortably write or draw on the touch surface 12 with the stylus 20 at an appropriate angle. It should be noted that, the lengths of the storage portion SP and the mating portion MP should be the same to ensure the stability of the electronic device 10 during support. In an embodiment where the coupling portion 150 is disposed on the outer surface of the storage portion SP, if the coupling portion 150 is located at the first end E1 of the storage portion SP, the bottom of the electronic device 10 may have a corresponding recess to accommodate the shape of the coupling portion 150. Alternatively, the coupling portion 150 may be disposed away from the first end E1. The present invention is not limited to these configurations.

The bottom 11 of the electronic device 10 may include a material with magnetic permeability, so that magnetic attraction can be generated with the second magnetic member M2 and the first magnetic member M1, allowing the storage portion SP and the mating portion MP to be magnetically attached to the bottom 11 of the electronic device 10 for use as a stand. For example, referring to FIG. 4, the electronic device 10 may include a magnetic attracting member 13. The magnetic attracting member 13 may be disposed on the bottom 11 of the electronic device 10, with its surface exposed from the bottom 11. The magnetic attracting member 13 may be made of a material having magnetic permeability, so as to be magnetically attracted and fixed by the first magnetic member M1 and the second magnetic member M2.

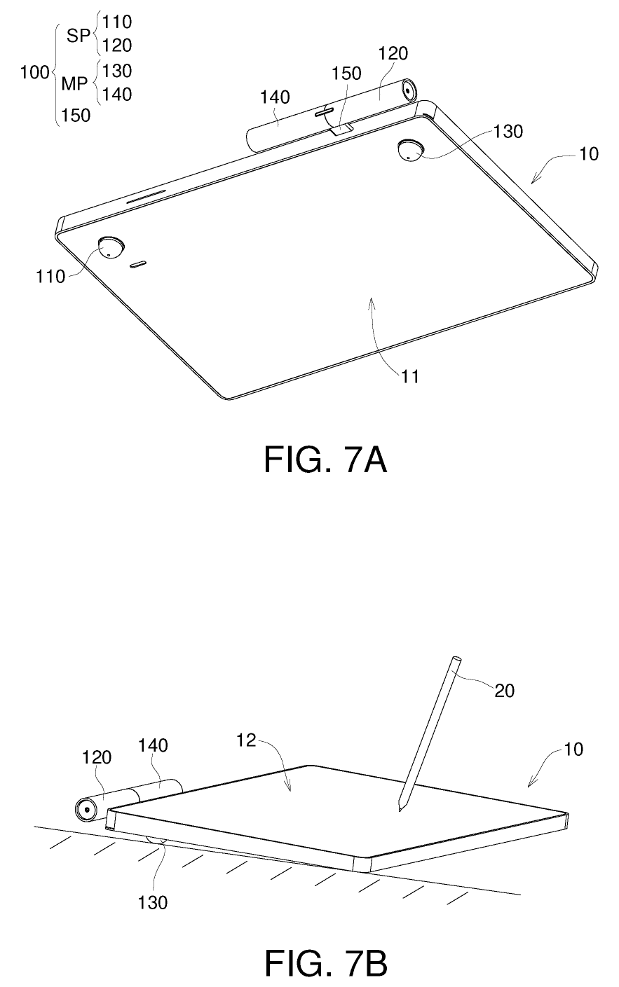

FIG. 7A illustrates another embodiment in which the pen placement structure 100 is used as a stand for the electronic device 10. FIG. 7B shows the embodiment of FIG. 7A from another perspective.

Referring to FIGS. 3, 7A and 7B, if the user considers that the tilt angle of the electronic device 10 in FIG. 6B is too steep for writing or drawing with the stylus 20, the first end member 110 and the second end member 130 may be removed from the first tubular member 120 and the second tubular member 140, respectively. The first end member 110 and the second end member 130 may then be magnetically attached to the bottom 11 of the electronic device 10, or to the magnetic attracting member 13 disposed on the bottom 11, via the third magnetic member M3 and the fourth magnetic member M4, respectively. This allows the first end member 110 and the second end member 130 to support the electronic device 10 on its bottom 11, providing different supporting angles, so that the user can comfortably write or draw on the touch surface 12 with the stylus 20 at a lower angle.

In this way, the pen placement structure 100 may be used not only for storing the stylus 20, but also as a stand for the electronic device 10. In addition, referring to FIGS. 3, 6A and 7A, when the pen placement structure 100 is used as a stand for the electronic device 10, the non-slip portions 111 and 131 of the first end member 110 and the second end member 130, and/or the shapes of the first end member 110 and the second end member 130, may provide anti-slip or positioning effects, making the support more stable.

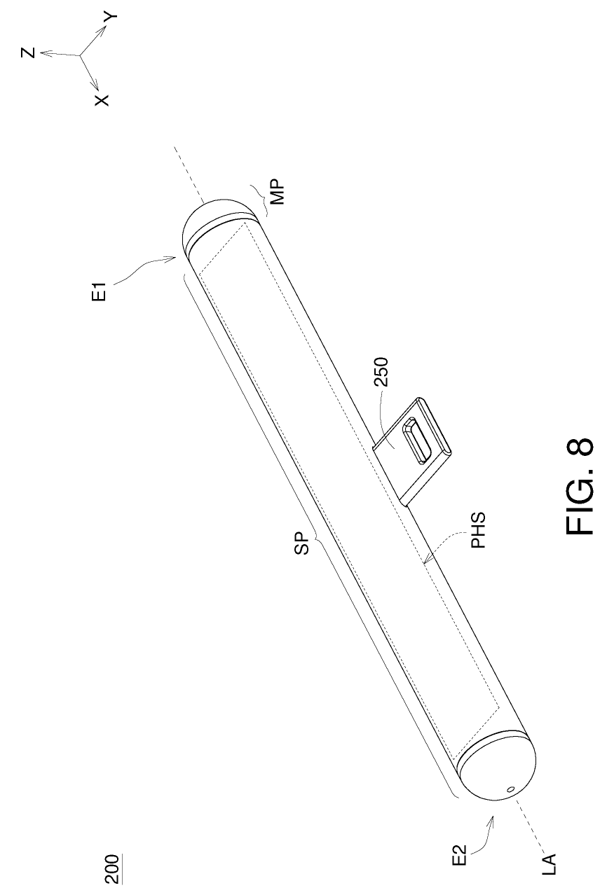

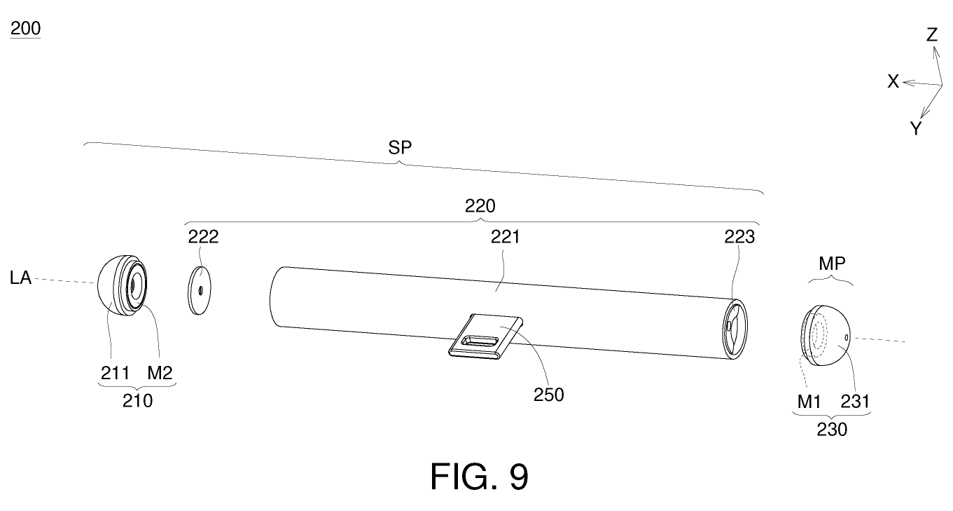

FIG. 8 is a perspective view of a pen placement structure 200 according to another embodiment of the present invention. FIG. 9 is a partially exploded view of the pen placement structure 200 of FIG. 8.

Referring to FIGS. 8 and 9, the pen placement structure 200 of the present embodiment has a shape generally similar to that of the pen placement structure 100 shown in FIG. 1, being a rod-shaped elongated structure. Some differences include that the mating portion MP is not an elongated extension member, but is similar to the first end member 110 and serves as the second end member 130 of the pen placement structure 100. Therefore, unlike the pen placement structure 100 of the embodiment shown in FIG. 1, the pen placement structure 200 cannot be separated from the middle to be used as a stand for the electronic device 10.

The storage portion SP and the mating portion MP may be separated from or coupled to each other. The storage portion SP is an elongated extension member having a longitudinal axis LA. The storage portion SP has a first end E1 and a second end E2 opposite each other along the longitudinal axis LA, wherein the first end E1 of the storage portion SP is an open end having an opening, through which the stylus may be inserted into the storage portion SP. Besides, the second end E2, as described above, may be a closed end or may have an opening, which will not be repeated here. In the present embodiment, the mating portion MP does not include an elongated extension member. The mating portion MP may be coupled to or separated from the first end E1 of the storage portion SP. When the mating portion MP is coupled to the first end E1 of the storage portion SP to close the opening of the first end E1, the interiors of the storage portion SP and the mating portion MP may be in communication with each other to form a pen holding space PHS for accommodating the stylus.

The pen placement structure 200 may include a coupling portion 250. The coupling portion 250 may at least partially protrude from the storage portion SP for engaging with a slot of the electronic device 10, or may be magnetically attached to one side of the electronic device 10, similar to the embodiment described above, and will not be repeated here.

The storage portion SP may include a tubular member 220 and a first end member 210. The first end member 210 is disposed on the tubular member 220 and is located at the second end E2 of the storage portion SP. The mating portion MP has a shape corresponding to the first end member 110 and is similar or equivalent to the second end member 130 of the pen placement structure 100. The first end member 210 and the second end member 230 may be coupled to or separated from the tubular member 220, respectively.

The first end member 210 and the second end member 230 may be magnetically coupled to the tubular member 220. The first end member 210 and the second end member 230 may respectively include a second magnetic member M2 and a first magnetic member M1. The second magnetic member M2 and the first magnetic member M1 may be magnetic elements having ferromagnetic properties. The tubular member 220 may include materials having magnetic permeability, so that magnetic attraction can be generated between the tubular member 220 and the second magnetic member M2, and between the tubular member 220 and the first magnetic member M1. Therefore, the first end member 210 and the second end member 230 are magnetically coupled to the tubular member 220, respectively. For example, the tubular member 220 may include a tubular housing 221 and two magnetic attracting members 222, 223. The two magnetic attracting members 222, 223 are respectively disposed on the ends of the tubular member 220 facing the first end member 210 and the second end member 230, and are made of materials having magnetic permeability, so as to be magnetically attracted and fixed by the second magnetic member M2 and the first magnetic member M1, respectively.

In addition, referring to FIG. 9, the first end member 210 and/or the second end member 230 may have a hemispherical or domed shape, but the present invention is not limited thereto. In other embodiments, the first end member 210 and/or the second end member 230 may have other shapes, such as square or other polygonal forms. The first end member 210 may include a non-slip portion 211. The non-slip portion 211 may be made of rubber, plastic, or a material treated on the surface to provide anti-slip properties. Similarly, the second end member 230 may also include a non-slip portion 231, which may likewise be made of rubber, plastic, or a material treated on the surface to provide anti-slip properties.

Referring to FIGS. 4 and 9, although the pen placement structure 200 of the present embodiment cannot be separated from the middle like the pen placement structure 100 of the embodiment shown in FIG. 1 to serve as a stand for the electronic device 10, a user can still remove the first end member 210 and the second end member 230 from the tubular member 220. The first end member 210 and the second end member 230 may be respectively magnetically attached to the bottom 11 of the electronic device 10 via the second magnetic member M2 and the first magnetic member M1, or to the magnetic attracting member 13 disposed on the bottom 11, so that the first end member 210 and the second end member 230 may support the electronic device 10 at its bottom 11.

In this way, the pen placement structure 200 may be used not only for storing the stylus 20, but also as a stand for the electronic device 10. In addition, when the pen placement structure 200 is used as a stand for the electronic device 10, the non-slip portions 211 and 231 of the first end member 210 and the second end member 230, and/or the shapes of the first end member 210 and the second end member 230, may provide anti-slip or positioning effects, making the support more stable.

In summary, embodiments of the present invention provide a pen placement structure including a storage portion, a coupling portion and a mating portion. The storage portion has a first end and a second end opposite each other along a longitudinal axis, and the first end has an opening. The coupling portion partially protrudes from the storage portion, so as to be connected to one side of an electronic device. The mating portion includes a first magnetic member, and the mating portion is selectively magnetically attached to the first end of the storage portion or to a bottom of the electronic device via the first magnetic member. When the mating portion is magnetically attached to the first end of the storage portion to close the opening, interiors of the storage portion and the mating portion are in communication with each other to form a pen holding space. When the mating portion is magnetically attached to the bottom of the electronic device, the mating portion supports the electronic device at the bottom of the electronic device.

Although the present invention has been disclosed above with reference to specific embodiments, it is not intended to limit the present invention. Those skilled in the art to which the present invention pertains may make various modifications and refinements without departing from the spirit and scope of the present invention. Therefore, the scope of the present invention shall be defined by the appended claims.

What is claimed is:

1. A pen placement structure comprising:
a storage portion having a first end and a second end opposite each other along a longitudinal axis, the first end having an opening; and
a mating portion comprising a first magnetic member, the mating portion being selectively magnetically attached to the first end of the storage portion or to a bottom of an electronic device via the first magnetic member;
wherein in response to the mating portion being magnetically attached to the first end of the storage portion to close the opening, interiors of the storage portion and the mating portion are in communication with each other to form a pen holding space; and
wherein in response to the mating portion being magnetically attached to the bottom of the electronic device, the mating portion supports the electronic device at the bottom of the electronic device.

2. The pen placement structure according to claim 1, wherein the storage portion comprises a second magnetic member located at the first end, the storage portion is selectively magnetically attached to the first magnetic member of the mating portion or to the bottom of the electronic device via the second magnetic member;
wherein in response to the storage portion being magnetically attached to the bottom of the electronic device, the storage portion supports the electronic device at the bottom of the electronic device.

3. The pen placement structure according to claim 1, wherein the second end is a closed end.

4. The pen placement structure according to claim 1, wherein the mating portion has a third end and a fourth end opposite each other along the longitudinal axis, the third end is an open end, and the first magnetic member is located at the third end.

5. The pen placement structure according to claim 4, wherein the fourth end is a closed end.

6. The pen placement structure according to claim 4, wherein the storage portion comprises a first end member and a first tubular member, the first end member is disposed on the first tubular member and located at the second end of the storage portion; the mating portion comprises a second end member and a second tubular member, the second end member is disposed on the second tubular member and located at the fourth end of the mating portion.

7. The pen placement structure according to claim 6, wherein the first end member and the second end member respectively comprise a third magnetic member and a fourth magnetic member, the first end member and the second end member are selectively magnetically attached to the first tubular member and the second tubular member or to the bottom of the electronic device via the third magnetic member and the fourth magnetic member;
in response to the first end member and the second end member being magnetically attached to the bottom of the electronic device, the first end member and the second end member support the electronic device at the bottom of the electronic device.

8. The pen placement structure according to claim 7, wherein the first tubular member comprises a first tubular housing and a first magnetic attracting member, the first magnetic attracting member is disposed on one end of the first tubular housing to be magnetically attached to the third magnetic member.

9. The pen placement structure according to claim 7, wherein the second tubular member comprises a second tubular housing and a second magnetic attracting member, the second magnetic attracting member is disposed on one end of the second tubular housing to be magnetically attached to the fourth magnetic member.

10. The pen placement structure according to claim 7, wherein the first end member and/or the second end member comprises a non-slip portion.

11. The pen placement structure according to claim 7, wherein the first end member and/or the second end member has a hemispherical or domed shape.

12. The pen placement structure according to claim 1, wherein the storage portion comprises a tubular member and a first end member, the first end member is disposed on the tubular member and located at the second end of the storage portion.

13. The pen placement structure according to claim 12, wherein the first end member comprises a second magnetic member, the first end member is selectively magnetically attached to the tubular member or to the bottom of the electronic device via the second magnetic member;
in response to the first end member being magnetically attached to the bottom of the electronic device, the first end member supports the electronic device at the bottom of the electronic device.

14. The pen placement structure according to claim 13, wherein the tubular member comprises a tubular housing, a first magnetic attracting member and a second magnetic attracting member, the first magnetic attracting member and the second magnetic attracting member are respectively disposed one ends of the tubular housing facing the first end member and the mating portion, so as to be magnetically attracted and fixed respectively by the second magnetic member and the first magnetic member.

15. The pen placement structure according to claim 13, wherein the mating portion is a second end member having a shape corresponding to the first end member, the second end member is selectively magnetically attached to the tubular member or to the bottom of the electronic device via the first magnetic member.

16. The pen placement structure according to claim 15, wherein the first end member and/or the second end member comprises a non-slip portion.

17. The pen placement structure according to claim 15, wherein the first end member and/or the second end member has a hemispherical or domed shape.

18. The pen placement structure according to claim 1, further comprising a coupling portion partially protruding from the storage portion, wherein the pen placement structure is connected to one side of the electronic device via the coupling portion.

19. The pen placement structure according to claim 1, further comprising a pen supporting seat disposed within the pen holding space.

20. The pen placement structure according to claim 19, further comprising a coupling portion disposed on the pen supporting seat and partially protruding from the storage portion, wherein the pen placement structure is connected to one side of the electronic device via the coupling portion.
